(19) United States
(12) Patent Application Publication
(10) Pub. No.: US 2018/0187987 A1
(43) Pub. Date: Jul. 5, 2018

(54) THERMALLY CONDUCTIVE STRUCTURE AND HEAT DISSIPATION DEVICE

(71) Applicant: Jiangsu Cnano Technology Co., Ltd., Jiangsu (CN)

(72) Inventors: Weizheng CAI, Jiangsu (CN); Zhiwei YANG, Jiangsu (CN); Tao ZHENG, Jiangsu (CN); Ou MAO, Jiangsu (CN); Meijie ZHANG, Jiangsu (CN)

(73) Assignee: Jiangsu Cnano Technology Co., Ltd., Jiangsu (CN)

(21) Appl. No.: 15/905,843

(22) Filed: Feb. 27, 2018

Related U.S. Application Data
(63) Continuation of application No. PCT/CN2016/000467, filed on Aug. 18, 2016.

(30) Foreign Application Priority Data
Aug. 31, 2015 (CN) 201510549129.2

(51) Int. Cl. F28F 21/02; F28F 3/00; F28D 15/02

(52) U.S. Cl. CPC F28F 21/02; H05K 7/2039; F28D 15/02; F28F 3/00

(57) ABSTRACT

A thermally conductive structure and a heat dissipation device are provided. The thermally conductive structure comprises a first thermally conductive layer and a second thermally conductive layer. The first thermally conductive layer comprises a graphene material and first carbon nanotubes, and the first carbon nanotubes are dispersed in the graphene material. The second thermally conductive layer is stacked on the first thermally conductive layer, and comprises a porous material and second carbon nanotubes, and the second carbon nanotubes are dispersed in the porous material. The heat dissipation device comprises the thermally conductive structure and a heat dissipation structure. The thermally conductive structure is in contact with a heat source, and the heat dissipation structure is connected to the thermally conductive structure. The thermally conductive structure and the heat dissipation device are characterized by thinness, and meet the need of light weight and thinness in modern thinned electronic products.

### CROSS-REFERENCE TO RELATED APPLICATION

This is a continuation of International Application No. PCT/CN2016/000467, filed on Aug. 18, 2016, which claims the priority benefits of China Application No. 201510549129.2, filed on Aug. 31, 2015. The entirety of each of the above-mentioned patent applications is hereby incorporated by reference herein and made a part of this specification.

### BACKGROUND

### Technical Field

The present invention relates to a thermally conductive structure and heat dissipation device, in particular to a thinned thermally conductive structure and heat dissipation device.

### Description of Related Art

With the development of science and technology, thinness and high efficiency are the consideration for the design and development of electronic devices. In the case of high-speed operation, the electronic components of electronic devices will inevitably produce more heat than the conventional electronic components. The high temperature operating environment may affect the characteristics of electronic components, and ultrahigh temperature is more likely to cause permanent damage to electronic components. Therefore, in order to cope with the trend toward thinned electronic devices, thinned heat dissipation devices have become an indispensable and important component in the current electronic devices.

The known heat dissipation devices generally include a radiator and a fan, the radiator is mounted on an electronic component (such as CPU) and generally made of aluminum or copper materials, and includes a base and a plurality of heat dissipation fins. When the heat generated by the electronic component is conducted to the radiator, the heat is conducted to the heat dissipation fins through the base and blown by the fan, so as to dissipate the heat generated by the electronic component.

However, for the heat dissipation device mentioned above, the radiator is too bulky to meet the need of light weight and thinness in the modern thinned electronic products. How to provide a thermally conductive structure and heat dissipation device, which have better thermal conduction effect and thinness feature and meet the need of light weight and thinness in the modern thinned electronic products, has become an important issue.

### SUMMARY

In view of the above problem, an object of the prevent invention is to provide a thermally conductive structure and heat dissipation device, which have better thermal conductivity and thinness feature and meet the need of light weight and thinness in the modern thinned electronic products.

In order to achieve the object of prevent invention, the technical solution adopted by the invention is as follows:

A thermally conductive structure comprises a first thermally conductive layer and a second thermally conductive layer, and is characterized in that the first thermally conductive layer comprises a graphene material and a plurality of first carbon nanotubes, and the first carbon nanotubes are dispersed in the graphene material; the second thermally conductive layer is stacked on the first thermally conductive layer, and comprises a porous material and a plurality of second carbon nanotubes, and the second carbon nanotubes are dispersed in the porous material;

the thermally conductive structure also comprises a plurality of thermally conductive particles, and the thermally conductive particles are dispersed in at least one of the first thermally conductive layer and the second thermally conductive layer;

the porous material is porous plastic which serves as a base material and also contains a large amount of air bubbles G;

since graphite particles exhibit good thermal conductivity and have excellent thermal conductivity for the plane formed by X/Y axes, the high-efficiency heat transfer is enabled through the first thermally conductive layer having the graphene material and first carbon nanotubes, so as to rapidly conduct heat from the heat source and transfer to the second thermally conductive layer; since the second thermally conductive layer has better Z-axis thermally conductive capability, when the heat is conducted to the second thermally conductive layer, owing to the high thermal conductivity of the second carbon nanotubes, the heat is conducted to the air bubbles G through the second carbon nanotubes and conducted upwards as well, and also the heat is conducted upwards through the porous material itself and the second carbon nanotubes; and

the thickness of the thermally conductive structure is in the range of 10 micrometers to 300 micrometers.

Further, the thermally conductive structure also comprises a functional layer, the functional layer is disposed on one surface of the first thermally conductive layer distal to the second thermally conductive layer, or disposed between the first thermally conductive layer and the second thermally conductive layer, or disposed on one surface of the second thermally conductive layer distal to the first thermally conductive layer.

Further, the functional layer is made of polyethylene terephthalate, epoxy resin, phenol resin, bismaleimides, nylon derivatives, polystyrene, polycarbonates, polyethylene, polypropylene, vinyl resin, acrylonitrile-butadiene-styrene copolymers, polyimide, polymethylmethacrylate, thermoplastic polyurethane, polyetheretherketone, polybutylene terephthalate, or polyvinylchloride.

Further, the thermally conductive particles are made of silver, copper, gold, aluminum, iron, tin, lead, silicon, silicon carbide, gallium arsenide, aluminum nitride, beryllium oxide or magnesium oxide.

Further, the thermally conductive particles are present in the first thermally conductive layer and the second thermally conductive layer.

In order to achieve the object of prevent invention, the present invention also discloses a heat dissipation device matched with a heat source, the heat dissipation device comprises the thermally conductive structure mentioned above, the thermally conductive structure being in contact with the heat source; and a heat dissipation structure, the heat dissipation structure being connected with the thermally conductive structure.

Further, the heat dissipation structure comprises one or more of a heat dissipation fin, a heat dissipation fan and a heat pipe.

As such, in the thermally conductive structure and heat dissipation device of the invention, the first thermally conductive layer comprises the plurality of first carbon nanotubes dispersed in the graphene material, and the second thermally conductive layer is stacked on the first thermally conductive layer and comprises the plurality of second carbon nanotubes dispersed in the porous material. With the structure of the first thermally conductive layer and second thermally conductive layer, the heat generated by the heat source can be rapidly conducted and then dissipated, and also the thermally conductive structure and heat dissipation device have the feature of thinness and meet the need of thinness in modern electronic products.

### BRIEF DESCRIPTION OF THE DRAWINGS

FIG. 1A is an exploded schematic view of a thermally conductive structure according to a preferred embodiment of the prevention invention.

FIG. 1B is a schematic side view of a thermally conductive structure according to a preferred embodiment of the prevention invention.

FIG. 1C is an enlarged schematic view of a region A of FIG. 1B.

FIG. 1D is an enlarged schematic view of a region B of FIG. 1B.

FIG. 2A to 2C are respective schematic side views of thermally conductive structures according to alternative embodiments of the prevention invention.

FIG. 3 is a schematic view of a heat dissipation device according to a preferred embodiment of the prevention invention.

### DESCRIPTION OF THE EMBODIMENTS

The thermally conductive structure and heat dissipation device according to the preferred embodiments of the prevention invention will be described in connection with the related drawings and figures, in which like elements are indicated by like numerals.

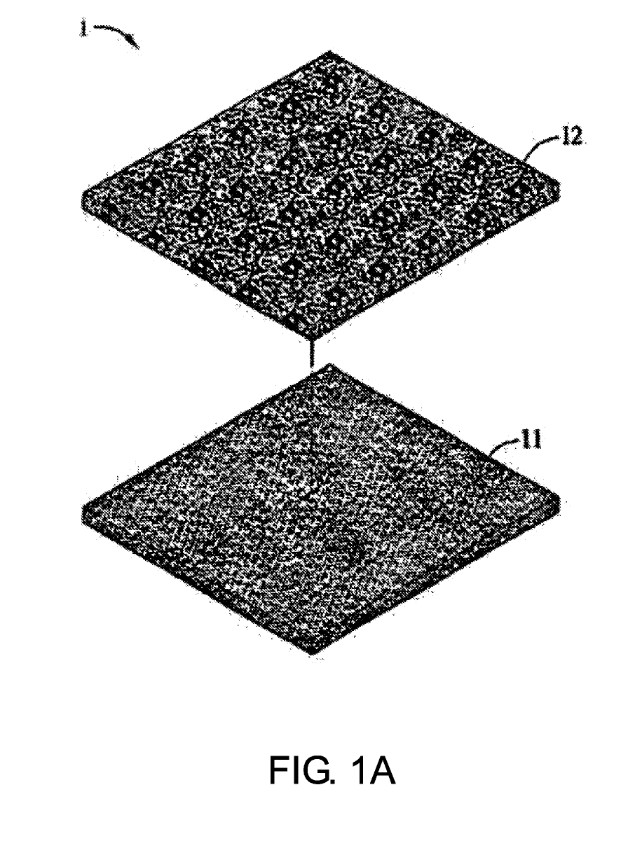

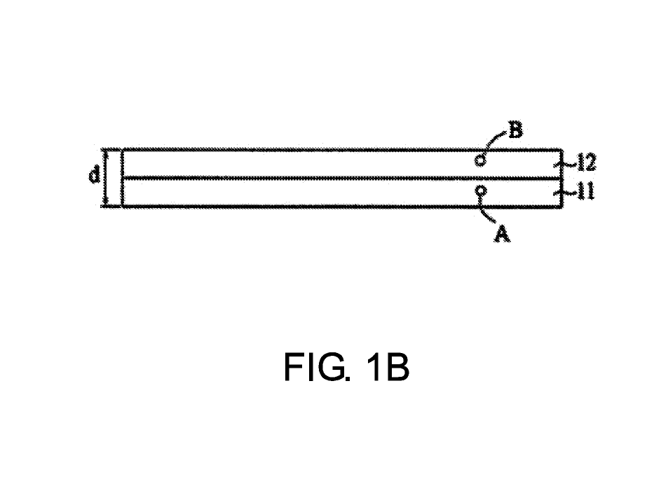

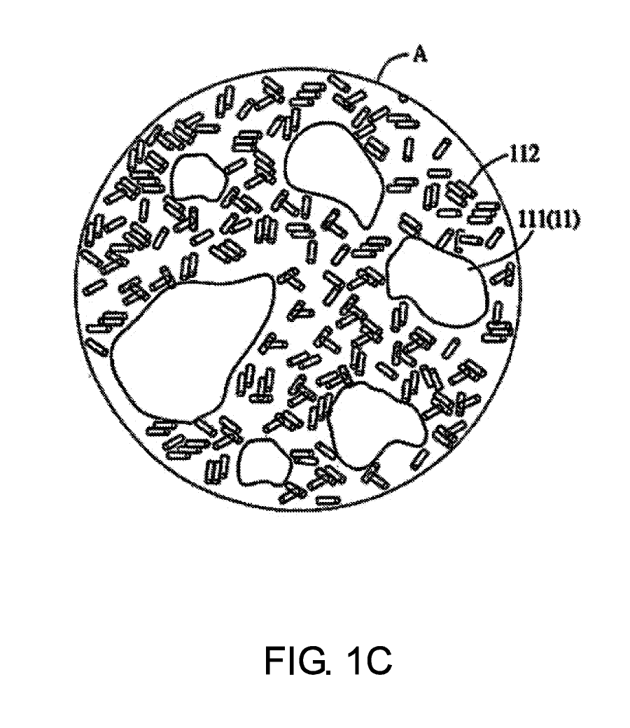

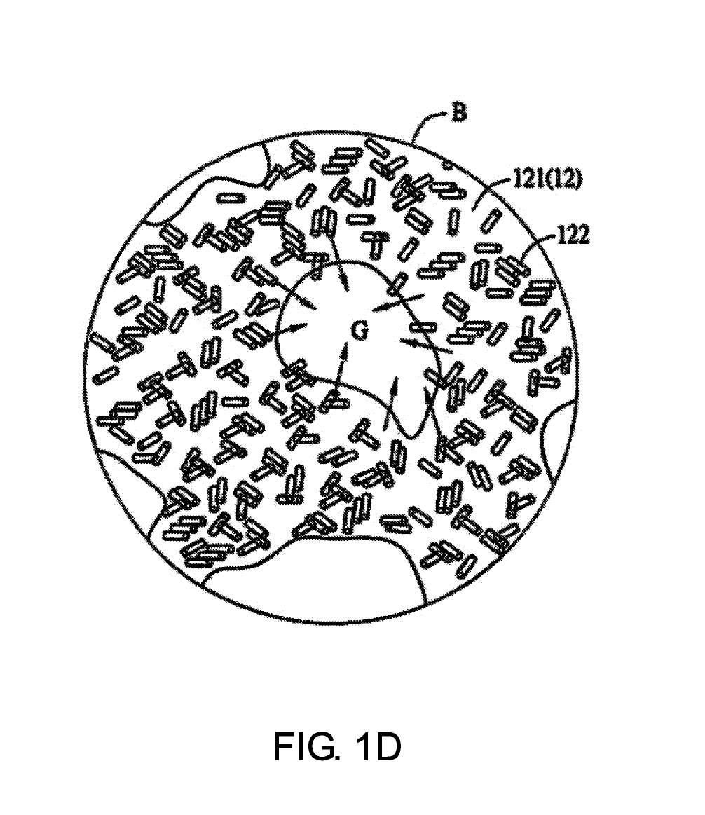

Referring to FIG. 1A to FIG. 1D, in which FIG. 1A and FIG. 1B are exploded schematic view and schematic view of a thermally conductive structure 1 according to an preferred embodiment of the prevention invention, respectively, and FIG. 1C and FIG. 1D are enlarged schematic views of regions A and B of FIG. 1B, respectively. Accordingly, FIG. 1C and FIG. 1D are merely indicative and not drawn according to the scale of actual elements.

The thermally conductive structure 1 can rapidly conduct the heat generated by a heat source (such as an electronic component) and comprises a first thermally conductive layer 11 and a second thermally conductive layer 12, and the first thermally conductive layer 11 and a second thermally conductive layer 12 are stacked to each other. In this embodiment, taking as an example, the second thermally conductive layer 12 is stacked on the first thermally conductive layer 11 (the first thermally conductive layer 11 is in contact with the heat source). In alternative embodiments, the first thermally conductive layer 11 is stacked on the second thermally conductive layer 12 (the second thermally conductive layer 12 is in contact with the heat source), which is not limited. The thickness d of the thermally conductive structure 1 is in the range of 10 micrometers to 300 micrometers, thus, a user can select the desired thickness based on the actual demand in the thinned electronic devices, to need the need of light weight and thinness in modern electronic products.

As shown in FIG. 1C, the first thermally conductive layer 11 comprises a graphite material 111 and a plurality of first carbon nanotubes (CNT) 112, and the first carbon nanotubes 112 are admixed in the graphite material 111. Wherein, the graphite material 111 is a material containing graphite as matrix, and may be natural or artificial graphite. The graphite material 111 (graphite particles) has a purity ranging from 70% to 99%, and the graphite particles have a particle size ranging from 5 nm to 3000 nm. Further, carbon nanotubes (first carbon nanotubes 112) are graphite pipes having high nano-sized diameter and length-width-height ratio, and the inner diameter of carbon nanotubes ranges from 0.4 nm to tens of nanometers, the outer diameter ranges from 1 nm to tens of nanometers and the length ranges from several nanometers to tens of nanometers. Carbon nanotubes are a kind of high thermally conductive material having a thermal conductivity coefficient typically greater than 6000 W/(m·k), which is extremely high as compared to the thermal conductivity coefficient of about 3320 W/(m·k) of high-purity diamond. In particular embodiments, the first thermally conductive layer 11 is formed by mixing carbon nanotubes (first carbon nanotubes 112) in the graphite material 111, adding a bonding agent (not shown) and then stirring, and curing and setting based on the actual demand of size and thickness. Since graphite particles exhibit good thermal conductivity and have excellent thermal conductivity for the plane formed by X/Y axes, the high-efficiency heat transfer is enabled through the first thermally conductive layer 11 having the graphene material 111 and first carbon nanotubes 112, so as to rapidly conduct heat from the heat source and transfer to the second thermally conductive layer 12.

Further, as shown in FIG. 1D, the second thermally conductive layer 12 comprises a porous material 121 and a plurality of second carbon nanotubes 122, and the second carbon nanotubes 122 are admixed in the porous material 121. Wherein, the porous material 121 may be foamed plastic, and is formed by, for example, adding a foaming material (such as carbon dioxide foaming agent, hydrochlorofluorocarbons (HCFC), hydrocarbons (e.g. cyclopentane), hydrogen fluoride, ADC foaming agent (e.g. N-nitroso compounds) or OBSH foaming agent (e.g. 4,4′-disulfonyl hydrazine diphenyl ether) to thermoplastic plastic (such as polystyrene (PS), polyethylene (PE), polyvinylchloride (PVC), ABS, PC, polyester, nylon or polyformaldehyde), followed by stirring; alternatively, is formed by, adding the foaming material to thermoplastic plastic (such as PU, polycyamelide resin, phenolic resin, urea formaldehyde resin, epoxy resin, polyorganosiloxane or polyimide (PI)), followed by stirring. The porous material 121 contains plastic as matrix and also contains a large amount of air bubbles G, thus, the porous material 121 may be composite plastic containing air as filler. Further, the second carbon nanotubes 122 have higher thermal conductivity than the first carbon nanotubes 112, which is not described in detail any more.

During implementation, the second thermally conductive layer 12 is formed by mixing the second carbon nanotubes 122 to the porous material 121 in liquid state and curing and setting based on the actual demand of size and thickness. When the heat is conducted to the second thermally conductive layer 12, owing to the high thermal conductivity of the second carbon nanotubes 122, the heat is conducted to the air bubbles G through the second carbon nanotubes 122 and conducted upwards as well, and also the heat is conducted upwards through the porous material 121 itself and the second carbon nanotubes 122.

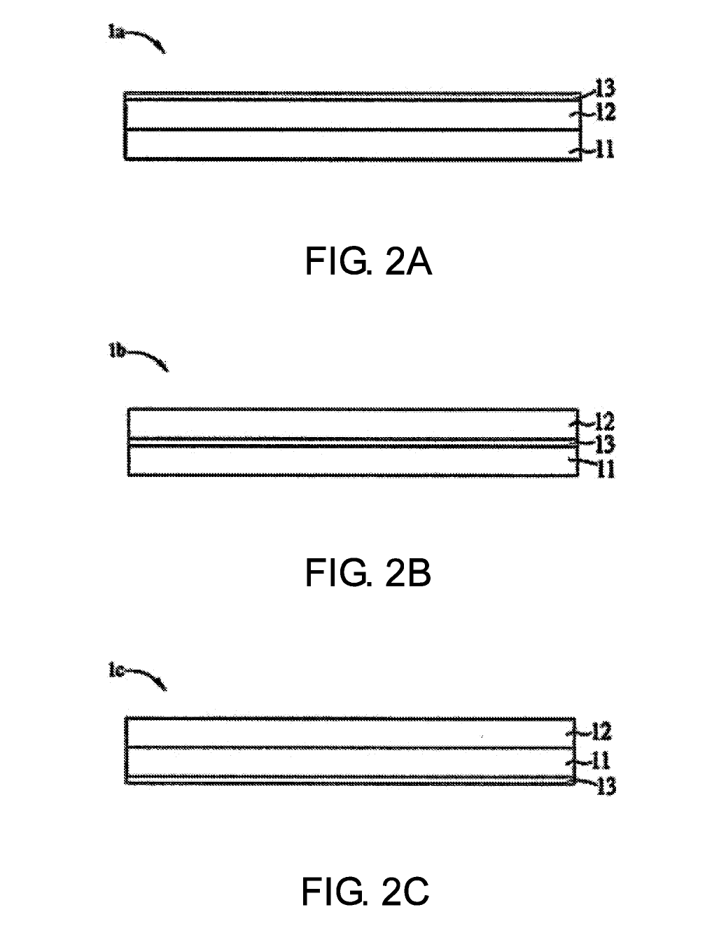

Further, refereeing to FIG. 2A to FIG. 2C, schematic side views of thermally conductive structures 1a, 1b and 1c according to alternative embodiments are shown separately.

As shown in FIG. 2A, the thermally conductive structure 1a differs from the thermally conductive structure 1 in that the thermally conductive structure 1a further comprises a functional layer 13, and the functional layer 13 is disposed on one surface of the second thermally conductive layer 12 distal to the first thermally conductive layer 11 (the upper surface of the second thermally conductive layer 12). Wherein, the functional layer 13 is made of thermosetting plastic, for example but not limited to epoxy resin (Epoxy), phenolic resin (Phenolic) or bismaleimide (BMI). Alternatively, the functional layer 13 is made of thermoplastic plastic, for example but not limited to Polyethylene terephthalate (PET), nylon derivatives, polystyrene, polycarbonate, polyethylene, polypropylene, vinyl resin (Vinyl), acrylonitrile-butadine-styrene copolymer (ABS), polyimide (PI), polymethylmethacrylate (PMMA), thermoplastic polyurethane (TPU), polyaryletherketone (PEEK), polybutylene terephthalate (PBT) or polyvinylchloride (PVC), and helps to conduct upwards the heat on the upper surface of the second theinially conductive layer 12 (enhancing the interfacial thermally conductive capability), thereby improving the overall thermal conduction efficiency.

Further, as shown in FIG. 2B, the thermally conductive structure 1b differs from the thermally conductive structure 1a in that the functional layer 13 of the thermally conductive structure 1b is disposed between the first thermally conductive layer 11 and the second thermally conductive layer 12, to help the thermal conduction on the interface between the first thermally conductive layer 11 and the second thermally conductive layer 12, thereby enhancing the interfacial thermally conductive capability.

Further, as shown in FIG. 2C, the thermally conductive structure 1c differs from the thermally conductive structure 1a in that the functional layer 13 of the thermally conductive structure 1c is disposed on one surface of the second thermally conductive layer 12 distal to the first thermally conductive layer 11 (the lower surface of the first thermally conductive layer 11, that is, located between the first thermally conductive layer 11 and the heat source), to help rapid conduction of the external heat of the thermally conductive structure 1c to the first thermally conductive layer 11, thereby enhancing the interfacial thermally conductive capability and thus improving the thermal conduction efficiency.

Further, other technical features of the thermally conductive structures 1a, 1b and 1c can be derived with reference to like elements of the thermally conductive structure 1, which is not described in detail.

It is noted that, based on different demands, in alternative embodiments, a plurality of thermally conductive particles (not shown) are admixed in the first thermally conductive layer 11, or in the second thermally conductive layer 12, or in both the first thermally conductive layer 11 and the second thermally conductive layer 12 in the above-mentioned embodiment. Wherein, the thermally conductive particles are made of a material having a thermal conductivity coefficient greater than 20 W/(m·k), for example, silver, copper, gold, aluminum, iron, tin, lead, silicon, silicon carbide, gallium arsenide, aluminum nitride, beryllium oxide or magnesium oxide or an alloy thereof, or ceramics such as aluminum oxide and boron nitride. Since the second thermally conductive layer has better Z-axis thermally conductive capability, the thermal conduction effect of the thermally conductive structure may be enhanced by the first thermally conductive layer 11 and/or the second thermally conductive layer 12; alternatively, the graphite material 111 may be added to the second thermally conductive layer 12, so that the second thermally conductive layer 12 comprises the graphite material 111 in addition to the porous material 121 and the second carbon nanotubes 122, as a result, the thermal conduction efficiency of the second thermally conductive layer 12 is improved.

Further, in some embodiments, the thermally conductive structure may be one layer of thermally conductive layers, for example, a single layer of the first thermally conductive layer 11 or the second thermally conductive layer 12, and also, a plurality of first thermally particles (not shown) are admixed in the single layer of the first thermally conductive layer 11 or the second thermally conductive layer 12, to enhance the thermal conduction effect. Further, in some embodiments, the graphite material 111 is added to the thermally conductive structure comprising a single layer of the second thermally conductive layer 12, which is not limited in the present invention.

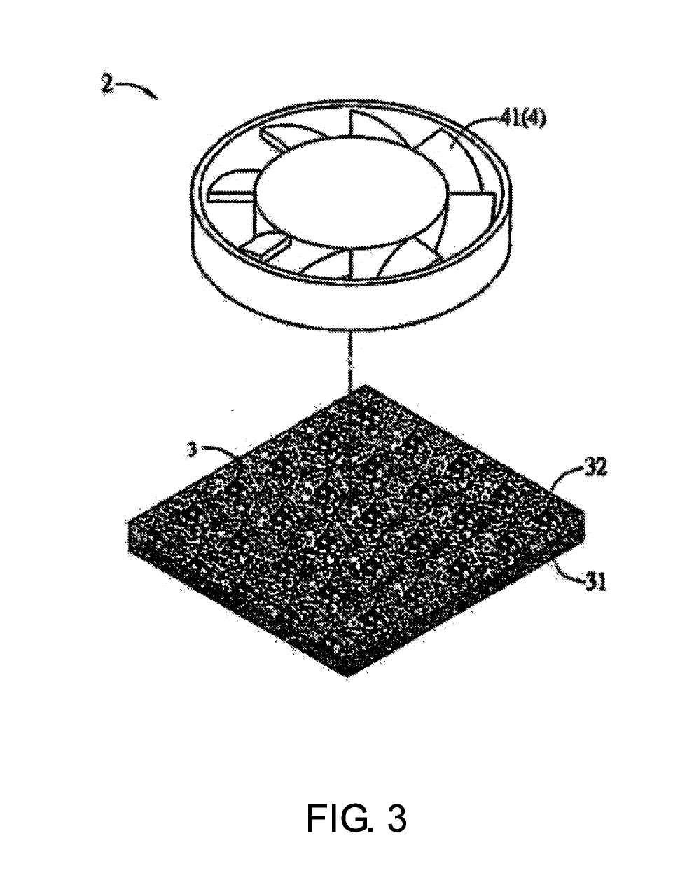

Referring to FIG. 3, a schematic view of a heat dissipation device 2 according to a preferred embodiment of the present invention is shown. The heat dissipation device 2 may be matched with a power component, a video card, a motherboard, a lighting device or other electronic components or electronic products, to help conduction of the heat generated by the heat source and dissipate the heat.

The heat dissipation device 2 comprises a thermally conductive structure 3 and a heat dissipation structure 4. Wherein, the thermally conductive structure 3 is in contact with the heat source (for example, directly disposed on the heat source and in contact with the heat source) and comprises a first thermally conductive layer 31 and a second thermally conductive layer 32, and the heat dissipation structure 4 is connected with the thermally conductive structure 3. Wherein, the heat source may be, for example but not limited to a central processing unit (CPU), and the thermally conductive structure 3 may be the above-mentioned thermally conductive structure 1, 1a, 1b, 1c or a variation thereof, and the particular technical features may refer to the foregoing descriptions and is not described in detail.

In this embodiment, the thermally conductive structure 3 of is disposed on the heat source, the first thermally conductive layer 31 is directly attached to a heat source (for example CPU) in need of heat dissipation, so as to rapidly conduct the heat generated by the heat source. Further, the heat dissipation structure 4 may comprises a heat dissipation fin, a heat dissipation fan or a heat pipe, or a combination thereof. In this embodiment, the heat dissipation structure 4 may be a heat dissipation fan 41, and when the heat generated by the heat source is conducted to the thermally conductive structure 3 and blown by the heat dissipation fan 41, the heat can be rapidly dissipated, thereby reducing the temperature of the heat source.

In summary, in the thermally conductive structure and heat dissipation device of the invention, the first thermally conductive layer of the thermally conductive structure comprises the plurality of first carbon nanotubes dispersed in the graphene material, and the second thermally conductive layer is stacked on the first thermally conductive layer and comprises the plurality of second carbon nanotubes dispersed in the porous material. With the structure of the first thermally conductive layer and second thermally conductive layer, the heat generated by the heat source can be rapidly conducted and then dissipated, and also the thermally conductive structure and heat dissipation device have the feature of thinness and meet the need of thinness in modern electronic products.

The foregoing descriptions are illustrative and not to limit this invention. Various equivalents and modifications may be made to the embodiments without departing from the spirit and scope of the invention, and all fall into the scope defined only by the appended claims.

What is claimed is:

1. A thermally conductive structure, comprising a first thermally conductive layer and a second thermally conductive layer, wherein the first thermally conductive layer comprises a graphene material and a plurality of first carbon nanotubes, and the first carbon nanotubes are dispersed in the graphene material; the second thermally conductive layer is stacked on the first thermally conductive layer, and comprises a porous material and a plurality of second carbon nanotubes, and the second carbon nanotubes are dispersed in the porous material;
the thermally conductive structure also comprises a plurality of thermally conductive particles, and the thermally conductive particles are dispersed in at least one of the first thermally conductive layer and the second thermally conductive layer;
the porous material is porous plastic containing plastic as matrix, and also contains a large amount of air bubbles;
since graphite particles exhibit good thermal conductivity and have excellent thermal conductivity for a plane formed by X/Y axes, the high-efficiency heat transfer is enabled through the first thermally conductive layer having the graphene material and first carbon nanotubes, so as to rapidly conduct heat from a heat source and transfer to the second thermally conductive layer; since the second thermally conductive layer has better Z-axis thermally conductive capability, when the heat is conducted to the second thermally conductive layer, owing to a high thermal conductivity of the second carbon nanotubes, the heat is conducted to the air bubbles through the second carbon nanotubes and conducted upwards as well, and also the heat is conducted upwards through the porous material itself and the second carbon nanotubes; and
a thickness of the thermally conductive structure is in a range of 10 micrometers to 300 micrometers.

2. The thermally conductive structure of claim 1, wherein the thermally conductive structure also comprises a functional layer, the functional layer is disposed on one surface of the first thermally conductive layer distal to the second thermally conductive layer, disposed between the first thermally conductive layer and the second thermally conductive layer, or disposed on one surface of the second thermally conductive layer distal to the first thermally conductive layer.

3. The thermally conductive structure of claim 2, wherein the functional layer is made from polyethylene terephthalate, epoxy resin, phenolic resin, bismaleimides, nylon derivatives, polystyrene, polycarbonates, polyethylene, polypropylene, vinyl resin, acrylonitrile-butadiene-styrene copolymers, polyimide, polymethylmethacrylate, thermoplastic polyurethane, polyetheretherketone, polybutylene terephthalate, or polyvinylchloride.

4. The thermally conductive structure of claim 1, wherein the thermally conductive particles are made of silver, copper, gold, aluminum, iron, tin, lead, silicon, silicon carbide, gallium arsenide, aluminum nitride, beryllium oxide or magnesium oxide.

5. The thermally conductive structure of claim 1, wherein the thermally conductive particles are present in the first thermally conductive layer and the second thermally conductive layer.

6. A heat dissipation device, matched with a heat source, wherein the heat dissipation device comprises the thermally conductive structure of claim 1, the thermally conductive structure being in contact with the heat source; and a heat dissipation structure, the heat dissipation structure being connected with the thermally conductive structure.

7. The heat dissipation device of claim 6, wherein the heat dissipation structure comprises one or more of a heat dissipation fin, a heat dissipation fan and a heat pipe.
